(19) United States
(12) Patent Application Publication
(10) Pub. No.: US 2023/0129843 A1
(43) Pub. Date: Apr. 27, 2023

(54) SEPARATE OPTOELECTRONIC SUBSTRATE

(71) Applicants: Robert Kalman, Mountain View, CA (US); Yong Ma, Mountain View, CA (US); Bardia Pezeshki, Mountain View, CA (US); Alexander Tselikov, Mountain View, CA (US); Cameron Danesh, Mountain View, CA (US)

(72) Inventors: Robert Kalman, Mountain View, CA (US); Yong Ma, Mountain View, CA (US); Bardia Pezeshki, Mountain View, CA (US); Alexander Tselikov, Mountain View, CA (US); Cameron Danesh, Mountain View, CA (US)

(21) Appl. No.: 18/050,258

(22) Filed: Oct. 27, 2022

Related U.S. Application Data
(60) Provisional application No. 63/272,567, filed on Oct. 27, 2021.

(51) Int. Cl. G02B 6/42; H01L 31/173

(52) U.S. Cl. CPC G02B 6/4246; G02B 6/4214; H01L 31/173

(57) ABSTRACT

A parallel optical interconnect having an optoelectronic substrate connected to a transceiver electronics substrate is disclosed. The optoelectronic substrate may hold optical transmitters and receivers and be electrically connected to the transceiver electronics substrate that may hold transmitter and receiver circuitries. The two substrates may be electrically connected with each other by inter-substrate interconnects, and the optoelectronic substrate may have through-substrate vias connecting the transmitters and receivers to the inter-substrate interconnects.

### CROSS-REFERENCE TO RELATED APPLICATIONS

This application claims the benefit of U.S. Provisional Pat. Application No. 63/272,567, filed on Oct. 27, 2021, the disclosure of which is incorporated by reference herein.

### FIELD OF INVENTION

The present invention is related generally to optical interconnects using microLEDs, and more particularly to substrates used in the optical interconnect.

### BACKGROUND OF THE INVENTION

Computing and networking performance requirements are seemingly ever-increasing. Prominent applications driving these requirements include data center servers, high-performance computing clusters, artificial neural networks, and network switches.

For decades, dramatic integrated circuit (IC) performance and cost improvements were driven by shrinking transistor dimensions combined with increasing die sizes, summarized in the famous Moore’s Law. Transistor counts in the billions have allowed consolidation onto a single system-on-a-chip (SoC) of functionality that was previously fragmented across multiple ICs. However, Moore’s Law appears to be reaching its limits as shrinking feature sizes below 10 nm results in decreasing marginal performance benefits with decreased yields and increased per-transistor costs.

Beyond these limitations, a single IC can only contain so much functionality, and that functionality is constrained because the IC’s process cannot be simultaneously optimized for different functionality, e.g., logic, DRAM, and I/O. Increasingly, improving system performance is dependent on implementing very high bandwidth interconnects between multiple ICs.

Unfortunately, compared to the on-chip connections, today’s chip-to-chip connections are typically much less dense and require far more power (for example normalized as energy per bit). These inter-IC connections are currently significantly limiting system performance. Specifically, the power, density, latency, and distance limitations of interconnects are far from what is desired.

New interconnect technologies that provide significant improvements in multiple performance aspects are highly desirable. It is well-known that optical interconnects may have fundamental advantages over electrical interconnects, even for relatively short interconnects of < < 1 meter. Unfortunately, implementation of optical interconnects for inter-IC connections may face a host of problems. Included in these problems is that of coupling light from one IC to another IC. Electrical interconnect technology for inter-IC communications at a substrate or circuit board level may be relatively well-developed. The same may not be as true for optical interconnect technology for inter-IC communications, particularly for high-throughput applications that preferably do not negatively impact existing modes of electrical interconnections.

### BRIEF SUMMARY OF THE INVENTION

Some embodiments provide a transceiver array for a parallel optical interconnect, comprising: a transceiver electronics substrate comprising a plurality of transmitter circuits and a plurality of receiver circuits; an optoelectronic substrate electrically connected to the transceiver electronics substrate by inter-substrate interconnects; a plurality of microLEDs, each microLED bonded to a pad on a first surface of the optoelectronic substrate, each microLED electrically connected to a corresponding transmitter circuit in the transceiver electronics substrate; and a plurality of photodetectors on or monolithically integrated into the optoelectronic substrate, each photodetector electrically connected to a corresponding receiver circuit in the transceiver electronics substrate.

In some embodiments the inter-substrate interconnects are on a surface of the optoelectronic substrate opposite the first surface. In some embodiments the optoelectronic substrate includes a plurality of first vias extending from the pads, to which one of the microLEDs is bonded, to some of the inter-substrate interconnects. In some embodiments each microLED includes a p-side and an n-side, and the p-side is bonded to the pad. In some embodiments the n-side of each microLED includes a contact, with a metal connection between each contact and a corresponding pad on the first surface of the optoelectronic substrate, each of the corresponding pads connected to some of the inter-substrate interconnects by second vias. In some embodiments each microLED includes a p-side and an n-side, and the n-side is bonded to the pad. In some embodiments the p-side of each microLED includes a contact, with a metal connection between each contact and a corresponding pad on the first surface of the optoelectronic substrate, each of the corresponding pads connected to some of the inter-substrate interconnects by second vias. In some embodiments the optoelectronic substrate comprises a silicon substrate, and the photodetectors are monolithically integrated in the optoelectronic substrate. In some embodiments the photodetectors are bonded to the first surface of the optoelectronic substrate. In some embodiments the optoelectronic substrate is made from an organic laminate. In some embodiments the optoelectronic substrate is made from a glass. Some embodiments further comprise an optical coupling system mounted to the optoelectronic substrate. In some embodiments the optical coupling system comprises a forty-five degree mirror and two lenses. In some embodiments the lenses are positioned such that the optical coupling system comprises a 4f imaging system. In some embodiments the 4f imaging system has a magnification M equal to 1.

These and other aspects of the invention are more fully comprehended upon review of this disclosure.

### BRIEF DESCRIPTION OF THE FIGURES

FIG. 1 is a diagram of a parallel optical interconnect, in accordance with aspects of the invention.

FIGS. 2A-B are block diagrams of an optical receiver and an optical transmitter, in accordance with aspects of the invention.

FIG. 3 shows a transceiver array having an optoelectronic substrate connecting the optical emitters and photodetectors to a transceiver electronics substrate, in accordance with aspects of the invention.

FIGS. 4A-C show different embodiments of transceiver arrays utilizing an optoelectronic substrate, in accordance with aspects of the invention.

FIG. 5 shows a close-up view of a microLED of a transceiver array attached to an optoelectronic substrate of a transceiver array, in accordance with aspects of the invention.

FIGS. 6A-B show cross-sections of different embodiments of an optical collector element in combination with a microLED and illustrating vertical optical transmission, in accordance with aspects of the invention.

FIGS. 7A-B show cross-sections of different embodiments of an optical collector element in combination with a photodetector and illustrating vertical optical transmission, in accordance with aspects of the invention.

FIG. 8A shows the different components of an optical coupling system, in accordance with aspects of the invention.

FIG. 8B shows a close-up view of the transceiver array coupled to the optical coupling system.

FIG. 9 shows an optoelectronic transceiver array coupled to a multicore fiber with an optical coupling system comprising two lenses, in accordance with aspects of the invention.

### DETAILED DESCRIPTION

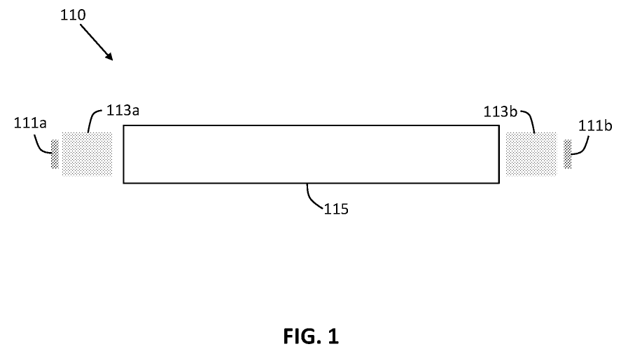

FIG. 1 shows a diagram of a parallel optical interconnect 110. In some embodiments, a parallel optical interconnect comprises a first optical transceiver array 111a, where the transceiver array comprises a plurality of optical transmitters and optical receivers, where each optical transmitter comprises a micro light emitting diode (microLED); a first coupling optics 113a, which may be in the form of a first optical coupling assembly that couples light between the first optical transceiver array and the first end of an optical transmission medium; an optical transmission medium 115; a second optical transceiver array 111b similar to or the same as the first optical transceiver array; and second coupling optics 113b, which may be a second optical coupling assembly similar to or the same as the first optical coupling assembly, which couples light from the second optical transceiver array to a second end of the optical transmission medium. The parallel optical interconnect comprises multiple “lanes,” where each lane comprises one transmitter in one transceiver array whose output light is relayed via coupling optics and the optical transmission medium to a receiver in the other transceiver array. In some embodiments, a parallel optical interconnect comprises 32 to 1024 lanes. In some embodiments, each parallel optical interconnect lane has a throughput in the range of 1 Gbps to 10 Gbps.

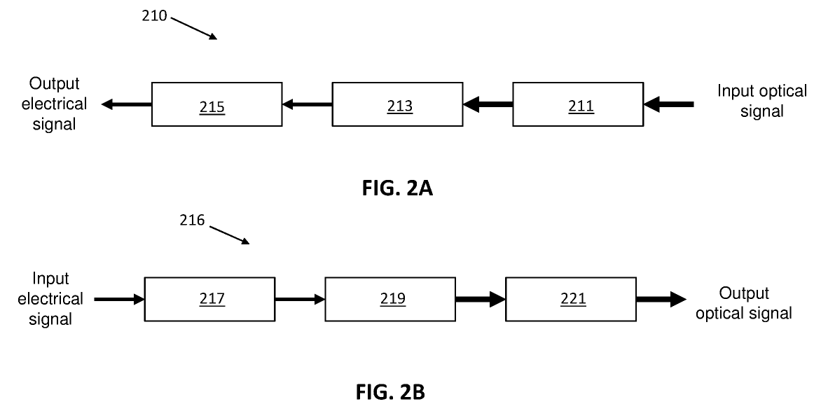

FIG. 2A shows a block diagram of an optical receiver 210. In some embodiments, each receiver in an optical transceiver array comprises collector optics 211, a photodetector 213, and a receiver circuit 215, with the collector optics and photodetector receiving an input optical signal and relaying such signal to the receiver circuit to produce an output electrical signal.

FIG. 2B shows a block diagram of an optical transmitter 216. In some embodiments, each transmitter in an optical transceiver array comprises a transmitter circuit 217, for example a drive circuit, a microLED 219, and an optical collector 221, where the output optical power of the microLED may be modulated by the drive circuit based on an electrical input signal to the drive circuit. In some embodiments a microLED is made from a p-n junction of a direct-bandgap semiconductor material. In some embodiments, a microLED is made from GaN. In some embodiments, a microLED are made from GaAs. In some embodiments, a microLED is made from InP.

In some embodiments a microLED is distinguished from a semiconductor laser (SL) as follows: (1) a microLED does not have an optical resonator structure; (2) the optical output from a microLED is almost completely spontaneous emission, whereas the output from a SL is dominantly stimulated emission; (3) the optical output from a microLED is temporally and spatially incoherent, whereas the output from a SL has significant temporal and spatial coherence; (4) a microLED is designed to be driven down to a zero minimum current, whereas a SL is designed to be driven down to a minimum threshold current, which is typically at least 1mA.

In some embodiments a microLED is distinguished from a standard LED by (1) having an emitting region of less than 10 µm x 10 µm; (2) frequently having cathode and anode contacts on top and bottom surfaces, whereas a standard LED typically has both positive and negative contacts on a single surface; (3) typically being used in large arrays for display and interconnect applications.

In some embodiments, each microLED used in a parallel optical interconnect is driven with a current in the range of 10 uA to 500 uA. In some embodiments, the per-bit energy consumed by each lane of a parallel optical interconnect is in the range of 0.05 pJ/bit to 1 pJ/bit.

### Optoelectronic Substrate

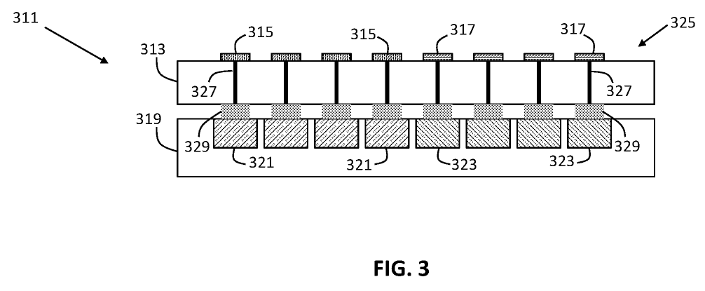

FIG. 3 shows a transceiver array 311 having an optoelectronic substrate 313 connecting optical emitters 315 and photodetectors 317 to a transceiver electronics substrate 319. In some embodiments, the transceiver array for a parallel optical interconnect comprises a transceiver electronics substrate that comprises one or more transmitter circuits 321 and one or more receiver circuits 323, and an optoelectronic subassembly 325 comprising an optoelectronic substrate, a plurality of optical emitters, and a plurality of photodetectors. In some embodiments, the optoelectronic substrate may be separate from the transceiver electronic substrate, where the two substrates are connected with each other by one or more inter-substrate interconnects 329. Each optical emitter in the optoelectronic subassembly is electrically connected to a transmitter circuit on the transceiver electronics substrate and each photodetector is electrically connected to a receiver circuit on the transceiver electronics substrate. The optoelectronic substrate may be over (or under) the transceiver electronics substrate, with the optical emitters and photodetectors on or about a surface of the optoelectronic substrate facing away from the transceiver electronics substrate. Inter-substrate interconnects, for example comprising one or more of pads, solder balls, or the like may electrically interconnect the optoelectronic substrate and the transceiver electronics substrate. The transceiver electronics substrate may be a transceiver electronics integrated circuit chip, in some embodiments.

In some embodiments, an electrical connection between each optical emitter or photodetector element comprises one or more through-substrate vias 327. In some embodiments, the vias may extend through the body of the optoelectronic substrate to connect the surface of the optoelectronic substrate facing away from the transceiver electronics substrate, having the optical emitters and photodetectors, with the opposite surface of the optoelectronic substrate facing the transceiver electronic substrate and having the one or more inter-substrate interconnect. In some embodiments, each inter-substrate interconnect between the optoelectronic substrate and the transceiver electronics substrate comprises a pad on each substrate connected by a solder bump, micro-bump, copper pillar, or direct bond interconnect. In some embodiments, the transceiver electronics substrate may comprise other circuitry in addition to transmitter and receiver circuits, such as circuits for input/output, computation, switching, and/or memory.

In some embodiments of an optoelectronic subassembly, the optoelectronic substrate is made from silicon. In some embodiments of an optoelectronic subassembly, the optoelectronic substrate is made from an organic laminate. In some embodiments of an optoelectronic subassembly, the optoelectronic substrate is made from a glass such as silicon dioxide or borosilicate glass.

### Emitters

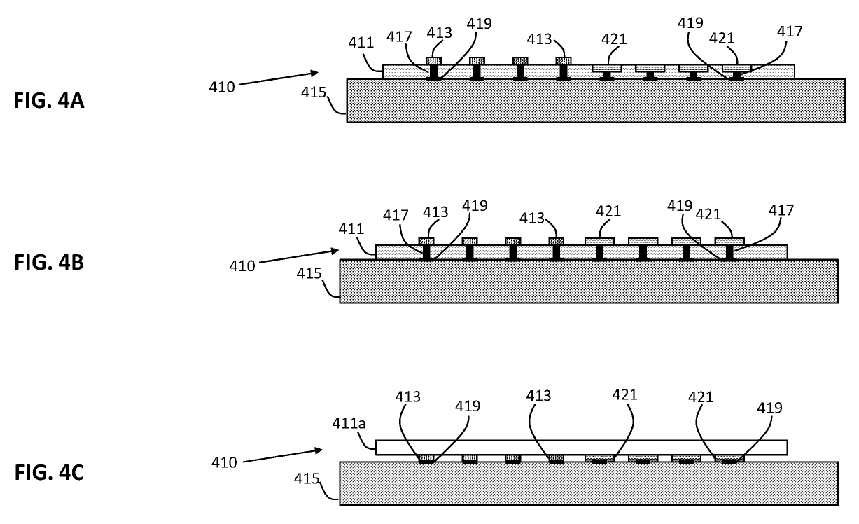

FIGS. 4A-C show different embodiments of transceiver arrays utilizing an optoelectronic substrate 411. In some embodiments of an optoelectronic subassembly 410, each optical emitter 413 comprises a microLED that is bonded to the top surface of the optoelectronic substrate, for instance using solder bonding or direct metal-metal bonding, as shown in FIGS. 4A-B. In some embodiments, the optical emitters on the top surface of the optoelectronic substrate may be connected to the transceiver electronics substrate 415, which may be positioned under the optoelectronic substrate, by the through-substrate vias 417. In some embodiments, the vias may extend through the body of the optoelectronic substrate and connect to bonding pads 419 that connect the optoelectronic substrate and the optical emitters to the transceiver electronic substrate. In some embodiments, the bonding pads may be considered as inter-substrate interconnects. In some embodiments, the transceiver electronics substrate may be a transceiver electronic integrated circuit.

In some embodiments, and as shown in FIG. 4C, the top (emitting) surface of each optical emitter is attached to the bottom surface of an optically transparent substrate 411a such that the light from each emitter transits the transparent substrate. The bottom surface of the optically transparent substrate may be the surface closest to and facing the transceiver electronics substrate. In some embodiments, the optical emitters may directly be bonded to the optically transparent substrate, and the optically transparent substrate may be attached to the transceiver electronics substrate by attaching the optical emitters (and in some embodiments the photodetectors) to bonding pads on the transceiver electronics substrate. As a result, the optical emitters may be effectively between the optically transparent substrate and the transceiver electronics substrate. In some embodiments the optically transparent substrate may be one continuous piece without any through-substrate vias.

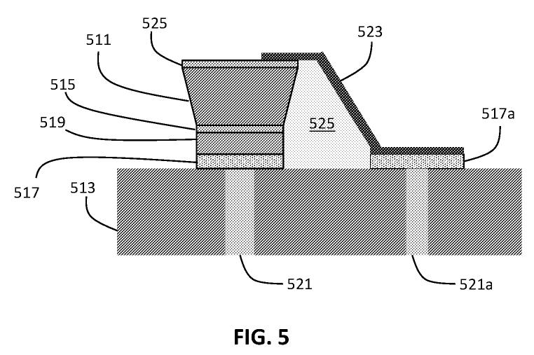

FIG. 5 shows a close-up view of a microLED 511 of a transceiver array attached to an optoelectronic substrate 513 of a transceiver array. In some embodiments, the bottom contact 515 of each microLED is electrically connected to a connecting pad 517 on the optoelectronic substrate. In some embodiments, the connection between the bottom contact of the microLED and the connecting pad may be done by soldering that creates a solder bond 519 between the two structures. In some embodiments, a microLED is bonded p-side down to a connecting pad that is on the optoelectronic substrate. In some embodiments, a microLED is bonded n-side down to a connecting pad that is on the optoelectronic substrate. The connecting pad to which the microLED is bonded may be connected to an opposing surface of the optoelectronic substrate by a via 521. Such opposing surface may be connected to the transceiver electronic substrate. In some embodiments, a metal connection 523 may be made from a top contact 525 of the microLED to another connecting pad 517a on the optoelectronic substrate, with the other connecting pad connected to the opposing surface of the optoelectronic substrate by another via 521a, allowing the microLED to be driven by a voltage across its p-contact and n-contact. Portions of the microLED other than the top contact may be insulated from the metal connection and the second connecting pad 517a by a dielectric 525. The solder bond and the first connecting pad 517 may also be insulated from the metal connection and the second connecting pad by the dielectric.

In some embodiments, there is an optical collector associated with each emitter. The optical collector collects light from its associated emitter such that the light emerging from the collector has a significantly smaller angular distribution than the light emerging from the emitter. This reduced angular distribution can greatly increase coupling into an optical transmission medium with a limited numerical aperture.

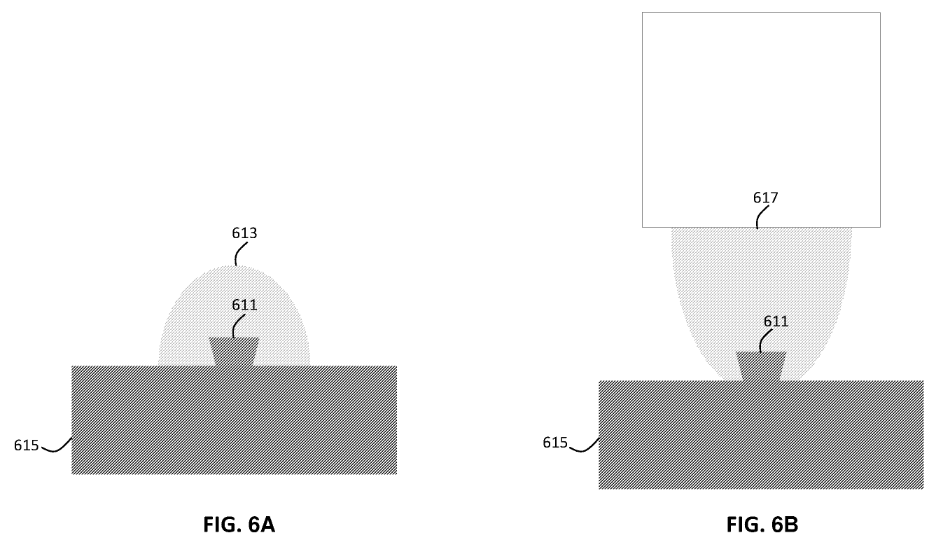

FIG. 6A shows a cross-section of one embodiment of an optical collector element in combination with a microLED 611. In some embodiments, each optical collector element comprises a refractive element 613, and the refractive element may encapsulate the emitter element (e.g. a microLED) on a substrate 615. The refractive element may have an approximately spherical surface, a parabolic surface, or may have an aspheric surface described. The refractive element is designed such that light from the emitter is collected into a smaller angular cone. Collection of light into a smaller cone can significantly improve optical coupling efficiency into a fiber core with a limited numerical aperture.

FIG. 6B shows a cross-section of another embodiment of an optical collector element in combination with a microLED. In some embodiments, each optical collector element comprises a reflector 617, for instance an approximately parabolic reflector that causes light emitted at an angle to the normal to be reflected into an angle closer to the normal. Reflection may be due to total internal reflection or a reflective layer may be applied to the surface of the reflector. In some embodiments, the reflector may enclose around the microLED on the substrate 615.

### Photodetectors

In some embodiments, photodetectors 421 are bonded to the top surface of the optoelectronic substrate 411, for instance by using solder bonding, direct bonding, or epoxy bonding, as shown in FIG. 4B. Such photodetectors may be made from silicon, SiGe, GaAs, or InP. In some embodiments, post-processing creates an electrical connection from top contacts on the photodetector to the optoelectronic substrate.

In some embodiments of an optoelectronic subassembly 410, the optoelectronic substrate is made from silicon and the photodetectors are monolithically integrated into the optoelectronic substrate, as shown in FIG. 4A. In some embodiments, the optoelectronic substrate may additionally comprise some receiver circuitry such as transimpedance amplifiers. In some embodiments, the photodetectors that are integrated to or on the top surface of the optoelectronic substrate may be connected to the transceiver electronics substrate 415, which may be positioned under the optoelectronic substrate, by the through-substrate vias 417. In some embodiments, the vias may extend through the body of the optoelectronic substrate and connect to bonding pads 419 that connect the optoelectronic substrate and the photodetectors to the transceiver electronic substrate. In some embodiments, the bonding pads may be considered as inter-substrate interconnects. In some embodiments, the transceiver electronics substrate may be a transceiver electronic integrated circuit.

In some embodiments, the top “active” surface of each photodetector is attached to the bottom surface of an optically transparent substrate 411a such that light transits the transparent substrate before hitting the photodetector, as shown in FIG. 4C. The bottom surface of the optically transparent substrate may be the surface closest to and facing the transceiver electronics substrate. In some embodiments, the photodetectors may directly be bonded to the optically transparent substrate by bonding pads, and the optically transparent substrate may be attached to the transceiver electronics substrate by attaching the photodetectors (and in some embodiments the optical emitters) to bonding pads on the transceiver electronics substrate. As a result, the photodetector may be effectively between the optically transparent substrate and the transceiver electronics substrate. In some embodiment, the optically transparent substrate may be one continuous piece without any through-substrate vias.

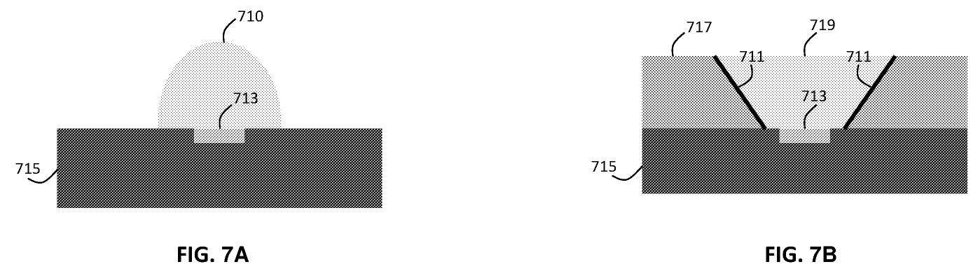

FIG. 7A shows a cross-section of one embodiment of an optical collector element in combination with a photodetector 713. In some embodiments, there is an optical collector element for each photodetector that is part of a receiver, where the optical collector element collects the light incident on it into a smaller spot. In some embodiments, each optical collector element comprises a refractive element 710 that encapsulate the photodetector. The refractive element may have an approximately spherical surface, parabolic surface, or may have an aspheric surface described. The refractive element is designed such that incident light having the optical signal is refracted towards the photodetector.

FIG. 7B shows a cross-section of another embodiment of an optical collector element in combination with a photodetector. In some embodiments, each optical collector element comprises a reflector structure 711, for instance an approximately parabolic reflector that causes light incident on it to be collected onto a photodetector. In some embodiments, the reflector structure may comprise a structure with a sloping surface that is made to be highly reflective. For instance, FIG. 7B shows a photodetector 713 on a substrate 715 and the reflective surfaces sloping away from the photodetector with increasing distance from the substrate. The photodetector may be in a gap of interconnect layers 717 on the substrate, with the gap increasing in width with distance from the substrate. The reflective surfaces on the interconnect layers, and the gap may be filled with encapsulant 719 to encapsulate the photodetector. The reflector structure is effective in collecting light that is propagating at large angles relative to the photodetector normal surface.

### Optical Coupling System

FIG. 1 shows that each transceiver array 113a-b that comprises a parallel optical interconnect 110 is coupled to the transmission medium by an optical coupling system 113a-b. In some embodiments of a parallel optical interconnect, the optical transmission medium comprises a multicore fiber or a fiber bundle. In some embodiments of a parallel optical interconnect, the optical transmission medium comprises free space into which optical elements such as lenses and mirrors may be inserted.

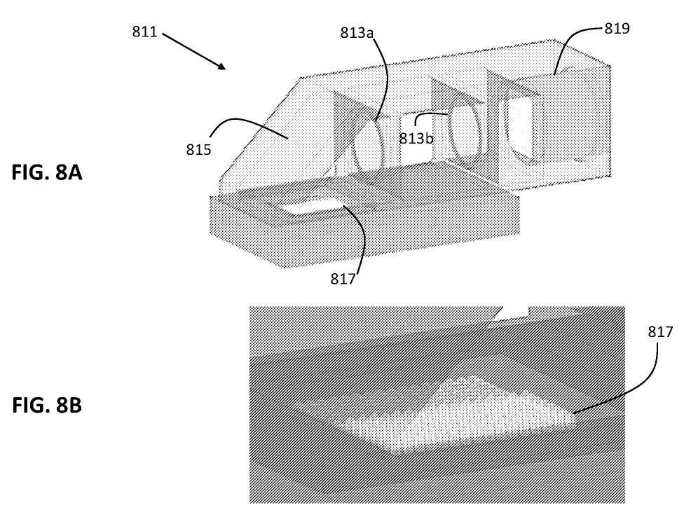

FIG. 8A shows the different components of an optical coupling system 811, in accordance with aspects of the invention. Some embodiments of an optical coupling system comprise a single lens. Some embodiments of an optical coupling system comprise two or more lenses 813a-b. Some embodiments of an optical coupling system comprise some combination of lenses, flat mirrors, and curved mirrors. For instance, FIG. 8A shows an optical coupling system comprising a 45° mirror 815 and two lenses, which images the optical transceiver array 817 onto the face of a multicore fiber 819, which a close-up view of the transceiver array coupled to the optical coupling system may be appreciated in FIG. 8B.

In some embodiments, the optical coupling system is mounted to the optoelectronic substrate. In some embodiments, the optical coupling system is positioned with respect to the optical emitter and photodetector elements using fiducial structures on the optoelectronic substrate. These fiducial structures may be photolithographically registered with respect to the arrays of emitter and photodetector elements. In some embodiments, these fiducial structures may be mechanical in nature, such as cavities fabricated in the optoelectronic substrate that are keyed to matching structures in the optical coupling system. In some embodiments, these fiducial structures may be designed to allow a machine vision system to accurately place the optical coupling system with respect to the arrays of emitter and photodetector elements.

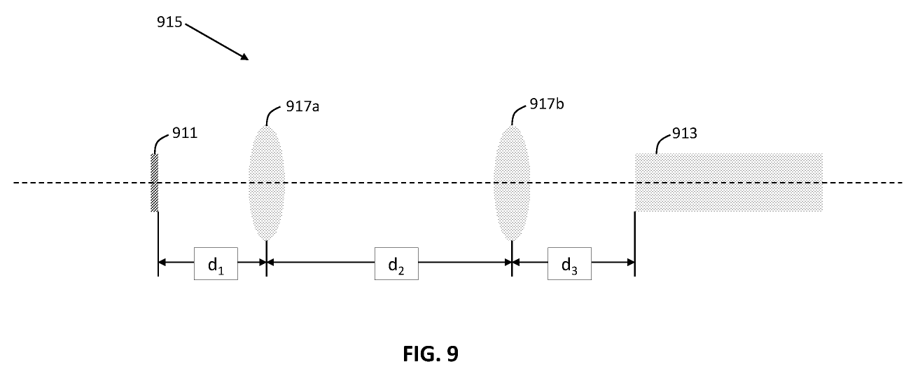

FIG. 9 shows an optoelectronic transceiver array 911 coupled to a multicore fiber 913 with an optical coupling system 915 comprising two lenses 917a-b with focal lengths fₐ and f_{b}, respectively. The two lenses 917a-b may be the same as the two lenses 813a-b shown in FIG. 8A. The first lens 917a with focal length fₐ is separated from the transceiver array by a distance d₁, and the second lens 917b with focal length f_{b} is separated from the multicore fiber end face by d₃. The two lenses are separated by a distance d₂. Some embodiments of an optical coupling system comprise a “4f” imaging system where d₁ = fₐ, d₂ = fₐ + f_{b}, and d₃ = f_{b}.

In some embodiments, the optical coupling system comprises an imaging system that images the emitter and detector elements of the transceiver array onto the face of the multicore fiber with a magnification M. In some embodiments, the magnification M = 1. In some embodiments, the magnification M is greater than 1 or less than one. The 4f configuration described above has a magnification M = f_{b}/fₐ.

In some embodiments, the design of the optical coupling system is such that by changing the distance between various elements (e.g., d₁, d₂, d₃ in FIG. 9) in a prescribed manner allows the optical magnification to be varied over some range. This may be useful to correct for certain component variances. For instance, if there is some variance in the focal lengths fₐ and f_{b} due to manufacturing variances, d₁, d₂, and d₃ can be changed to ensure the optoelectronic transceiver array is imaged onto the end face of the multicore fiber with the desired magnification. Similarly, if there is some variance in the diameter of the multicore fiber such that the positions of the individual cores in the fiber scale with the fiber diameter, d₁, d₂, and d₃ can be changed to ensure the optoelectronic transceiver array is imaged onto the end face of the multicore fiber with the magnification adjusted to maximize coupling efficiency into the fiber cores.

Although the invention has been discussed with respect to various embodiments, it should be recognized that the invention comprises the novel and non-obvious claims supported by this disclosure.

What is claimed is:

1. A transceiver array for a parallel optical interconnect, comprising:
a transceiver electronics substrate comprising a plurality of transmitter circuits and a plurality of receiver circuits;
an optoelectronic substrate electrically connected to the transceiver electronics substrate by inter-substrate interconnects;
a plurality of microLEDs, each microLED bonded to a pad on a first surface of the optoelectronic substrate, each microLED electrically connected to a corresponding transmitter circuit in the transceiver electronics substrate; and
a plurality of photodetectors on or monolithically integrated into the optoelectronic substrate, each photodetector electrically connected to a corresponding receiver circuit in the transceiver electronics substrate.

2. The transceiver array of claim 1, wherein the inter-substrate interconnects are on a surface of the optoelectronic substrate opposite the first surface.

3. The transceiver array of claim 2, wherein the optoelectronic substrate includes a plurality of first vias extending from the pads, to which one of the microLEDs is bonded, to some of the inter-substrate interconnects.

4. The transceiver array of claim 3, wherein each microLED includes a p-side and an n-side, and the p-side is bonded to the pad.

5. The transceiver array of claim 4, wherein the n-side of each microLED includes a contact, with a metal connection between each contact and a corresponding pad on the first surface of the optoelectronic substrate, each of the corresponding pads connected to some of the inter-substrate interconnects by second vias.

6. The transceiver array of claim 3, wherein each microLED includes a p-side and an n-side, and the n-side is bonded to the pad.

7. The transceiver array of claim 6, wherein the p-side of each microLED includes a contact, with a metal connection between each contact and a corresponding pad on the first surface of the optoelectronic substrate, each of the corresponding pads connected to some of the inter-substrate interconnects by second vias.

8. The transceiver array of claim 1, wherein the optoelectronic substrate comprises a silicon substrate, and the photodetectors are monolithically integrated in the optoelectronic substrate.

9. The transceiver array of claim 1, wherein the photodetectors are bonded to the first surface of the optoelectronic substrate.

10. The transceiver array of claim 9, wherein the optoelectronic substrate is made from an organic laminate.

11. The transceiver array of claim 9, wherein the optoelectronic substrate is made from a glass.

12. The transceiver array of claim 1, further comprising an optical coupling system mounted to the optoelectronic substrate.

13. The transceiver array of claim 12, wherein the optical coupling system comprises a forty-five degree mirror and two lenses.

14. The transceiver array of claim 13, wherein the lenses are positioned such that the optical coupling system comprises a 4f imaging system.

15. The transceiver array of claim 14, wherein the 4f imaging system has a magnification M equal to 1.
